(19) United States
(12) Patent Application Publication
(10) Pub. No.: US 2010/0207215 A1
(43) Pub. Date: Aug. 19, 2010

(54) Semiconductor Device and Method of Producing the Same

(76) Inventor: Tadashi NARITA, Miyagi (JP)

Correspondence Address: Kazunao Kubotera;KUBOTERA & ASSOCIATES, LLC, Suite 202, 200 Daingerfield Road, Alexandria, VA, 22314, US

(21) Appl. No.: 12/694,393

(22) Filed: Jan. 27, 2010

(30) Foreign Application Priority Data
Feb. 16, 2009 (JP) 2009-032762

(51) Int. Cl. H01L 27/092; H01L 21/3205

(52) U.S. Cl. 257/377; 438/655; 257/E27.062; 257/E21.296

(57) ABSTRACT

A semiconductor device includes a semiconductor substrate; an N-channel type transistor forming region formed on the semiconductor substrate; a P-channel type transistor forming region formed on the semiconductor substrate and arranged adjacent to the N-channel type transistor forming region; and a gate electrode formed on the semiconductor substrate over the N-channel type transistor forming region and the P-channel type transistor forming region. The gate electrode has a boundary inclusion portion formed in a first region including a boundary line between the N-channel type transistor forming region and the P-channel type transistor forming region and a boundary exclusion portion formed in a second region not including the boundary line. The gate electrode includes a conductive silicon layer and a metal silicide layer formed on the conductive silicon layer. The metal silicide layer has a first thickness in the boundary inclusion portion and a second thickness from the first thickness in the boundary exclusion portion.

### BACKGROUND OF THE INVENTION AND RELATED ART STATEMENT

The present invention relates to a semiconductor device and a method of the semiconductor device. More specifically, the present invention relates to a semiconductor device having a dual-gate structure, in which a metal silicide layer is formed on a conductive silicon layer. The present invention further relates to a method of producing the semiconductor device.

Recently, as an electrical device has a smaller size, a smaller thickness, a smaller weight, or a higher performance, it is necessary to reduce a size or improve a performance of a semiconductor device used in the electrical device.

FIG. 12(A) is a schematic plan view showing a conventional semiconductor device 100. The conventional semiconductor device 100 has a dual-gate structure having a gate electrode 106 formed of an N-type conductive layer and a P-type conductive layer. In order to reduce a size of the conventional semiconductor device 100, it is necessary to reduce a gate width of the gate electrode 106 disposed over an N-type transistor forming region 102 and a P-type transistor forming region 104, thereby reducing a layout area (an area of the N-type transistor forming region 102 and the P-type transistor forming region 104).

When the gate width of the gate electrode 106 is reduced, however, a metal silicide layer constituting the gate electrode 106 tends to be peeled off or aggregated locally (near a boundary line L between the N-type transistor forming region 102 and the P-type transistor forming region 104), thereby creating a metal silicide layer missing region. Accordingly, a resistivity of the gate electrode 106 increases extraordinarily.

FIG. 13 is a graph showing a relationship between a cumulative probability of the resistivity of the gate electrode 106 and the gate width of the gate electrode 106. In this case, the metal silicide layer is formed of a cobalt silicide.

As shown in FIG. 13, when the gate width of the gate electrode 106 is decreased and becomes less than 0.18 μm, resistivity abnormality occurs in the gate electrode 106 near the boundary line L.

Similarly, when the thickness of the metal silicide layer of the gate electrode 106 is decreased, the resistivity abnormality is considered to occur in the gate electrode 106 near the boundary line L more easily. In other word, when the metal silicide layer has a larger thickness, it is possible to prevent the resistivity abnormality. On the other hand, when the metal silicide layer has a larger thickness, a sheet resistivity decreases. Accordingly, when the gate electrode 106 situated at an area other than the boundary line L is used as a resistor element, it is difficult to obtain a necessary level of resistivity.

In order to solve the problem described above, Patent Reference 1 has proposed a conventional semiconductor device 110 shown in FIG. 12(B). FIG. 12(B) is a schematic plan view showing the conventional semiconductor device 110.

In the conventional semiconductor device 110, a gate electrode 116 has a large width near a boundary line L between an N-type transistor forming region 112 and a P-type transistor forming region 114. Accordingly, it is possible to increase a gate width of the gate electrode 116 without increasing an entire gate width of the gate electrode 116. As a result, it is possible to prevent a metal silicide layer constituting the gate electrode 116 from being peeled off or aggregated, thereby preventing damage of the metal silicide layer.

In the conventional semiconductor device 110, however, a layout area is determined by the gate width of the gate electrode 116 near the boundary line L. As a result, when the gate width of the gate electrode 116 near the boundary line L is increased, the layout area tends to increase inevitably, thereby increasing a size of the conventional semiconductor device 110.

Patent Reference 1: Japanese Patent Publication No. 2001-77210

Patent Reference 2 has disclosed a technology for producing a conventional semiconductor device having an electrode or a wiring portion with a low resistivity. The conventional semiconductor device includes a semiconductor layer having regions each with a P-type impurity, an N-type impurity and a (P+N)-type impurity doped therein, respectively. After an impurity precipitate layer on each of the regions is removed through a thermal process, a film formed of a metal material is disposed, and another thermal process is performed, so that a silicide layer is formed on the semiconductor layer.

Alternatively, an impurity is introduced into the impurity precipitate layer, and then a metal material film is formed on the impurity precipitate layer. Afterward, the thermal process is performed, so that a silicide layer is formed on the semiconductor layer.

Patent Reference 2: Japanese Patent Publication No. 2006-186285

In view of the problems described above, an object of the present invention is to provide a semiconductor device and a method of producing the semiconductor device capable of solving the problems of the conventional semiconductor device and the conventional method of producing the semiconductor device. In the present invention, the semiconductor device is capable of adjusting a resistivity of a gate electrode regardless of a thickness of a metal silicide layer.

Further objects and advantages of the invention will be apparent from the following description of the invention.

### SUMMARY OF THE INVENTION

In order to attain the objects described above, according to a first aspect of the present invention, a semiconductor device includes a semiconductor substrate; an N-channel type transistor forming region formed on the semiconductor substrate; a P-channel type transistor forming region formed on the semiconductor substrate and arranged adjacent to the N-channel type transistor forming region; and a gate electrode formed on the semiconductor substrate over the N-channel type transistor forming region and the P-channel type transistor forming region. The gate electrode has a boundary inclusion portion formed in a first region including a boundary line between the N-channel type transistor forming region and the P-channel type transistor forming region and a boundary exclusion portion formed in a second region not including the boundary line. The gate electrode includes a conductive silicon layer and a metal silicide layer formed on a surface of the conductive silicon layer. The metal silicide layer has a first thickness in the boundary inclusion portion and a second thickness in the boundary exclusion portion, and the first thickness is different from the second thickness.

In the first aspect of the present invention, the semiconductor device includes the N-channel type transistor forming region formed on the semiconductor substrate and the P-channel type transistor forming region formed on the semiconductor substrate and arranged adjacent to the N-channel type transistor forming region. The gate electrode is formed on the semiconductor substrate over the N-channel type transistor forming region and the P-channel type transistor forming region, thereby constituting a dual-gate structure.

Further, the gate electrode has the boundary inclusion portion formed in the first region including the boundary line between the N-channel type transistor forming region and the P-channel type transistor forming region, and the boundary exclusion portion formed in the second region not including the boundary line. The gate electrode includes the conductive silicon layer and the metal silicide layer formed on the surface of the conductive silicon layer. The metal silicide layer has the first thickness in the boundary inclusion portion and the second thickness in the boundary exclusion portion, and the first thickness is different from the second thickness. In other word, the thickness of the metal silicide layer near the boundary line (an NP connection portion) is different from the thickness thereof at a portion other than the boundary line (the NP connection portion).

In the first aspect of the present invention, the following effect can be obtained. As described above, the semiconductor device includes the N-channel type transistor forming region, the P-channel type transistor forming region arranged adjacent to the N-channel type transistor forming region, and the gate electrode disposed over the N-channel type transistor forming region and the P-channel type transistor forming region. In order to suppress resistivity abnormality near the boundary line between the N-channel type transistor forming region and the P-channel type transistor forming region, it is necessary to increase the thickness of the metal silicide layer of the gate electrode. When the gate electrode is used as a resistor element, a resistivity of the gate electrode depends on the thickness of the metal silicide layer. Accordingly, in this case, it is necessary to adjust the thickness of the metal silicide layer according to a desired resistivity.

As described above, in the first aspect of the present invention, the thickness of the metal silicide layer near the boundary line (the NP connection portion) is different from the thickness thereof at a portion other than the boundary line (the NP connection portion). In other words, it is possible to freely adjust the thickness of the metal silicide layer near the boundary line and the thickness thereof at a portion other than the boundary line. Accordingly, it is possible to freely adjust a resistivity of the gate electrode regardless of the thickness of the metal silicide layer near the boundary inclusion portion.

According to a second aspect of the present invention, in the semiconductor device in the first aspect, the metal silicide layer has the first thickness in the boundary inclusion portion and the second thickness in the boundary exclusion portion, and the first thickness is greater than the second thickness.

In the second aspect of the present invention, the following effect can be obtained. As described above, the metal silicide layer has the first thickness in the boundary inclusion portion greater than the second thickness in the boundary exclusion portion. More specifically, the thickness of the metal silicide layer near the boundary line (the NP connection portion) is greater than the thickness thereof at a portion other than the boundary line (the NP connection portion). Accordingly, it is possible to prevent the metal silicide layer from being peeled off or aggregated.

As a result, it is possible to prevent resistivity abnormality, in which a gate current does not flow smoothly in the gate electrode on a boundary line between the N-channel type transistor forming region and the P-channel type transistor forming region. Further, it is not necessary to excessively increase a gate width of the gate electrode in order to suppress the resistivity abnormality. Accordingly, it is possible to reduce areas of the N-channel type transistor forming region and the P-channel type transistor forming region, thereby reducing a size of the semiconductor device.

Further, the metal silicide layer has the second thickness in the boundary exclusion portion having a relatively small level. Accordingly, when the gate electrode in an area away from the boundary line is used as a resistor element, it is possible to obtain a sufficient level of resistivity.

According to a third aspect of the present invention, in the semiconductor device in the first aspect or the second aspect, the metal silicide layer has the first thickness in the boundary inclusion portion and the second thickness in the boundary exclusion portion, and the conductive silicon layer has a third thickness in the boundary inclusion portion and a fourth thickness in the boundary exclusion portion. A sum of the first thickness and the third thickness is more than 70% and less than 130% of a sum of the second thickness and the fourth thickness.

In the third aspect of the present invention, the following effect can be obtained. When the metal silicide layer and the silicon conductive layer of the gate electrode are formed, the metal silicide layer and the silicon conductive layer may have thicknesses with variance in some extent, and the variance is generally within more than 70% and less than 130%.

In the third aspect of the present invention, the metal silicide layer has the first thickness in the boundary inclusion portion and the second thickness in the boundary exclusion portion within the range described above, and the conductive silicon layer has the third thickness in the boundary inclusion portion and the fourth thickness in the boundary exclusion portion within the range described above. In other words, the sum of the first thickness and the third thickness is substantially equal to the sum of the second thickness and the fourth thickness (within the range of the variance).

As described above, the sum of the first thickness and the third thickness is substantially equal to the sum of the second thickness and the fourth thickness. In other words, a difference between the first thickness and the second thickness of the metal silicide layer is adjusted through the third thickness and the fourth thickness of the conductive silicon layer. Accordingly, when one of the first thickness and the second thickness of the metal silicide layer is larger than the other, one of the third thickness and the fourth thickness of the conductive silicon layer is adjusted, thereby decreasing the total thickness and reducing the size of the semiconductor device.

According to a fourth aspect of the present invention, a method of producing a semiconductor device includes:

a conductive silicon layer forming step of forming a conductive silicon layer over an N-channel type transistor forming region and a P-channel type transistor forming region formed on a semiconductor substrate;

a first SiO₂ layer forming step of forming a first SiO₂ layer on an entire surface of the semiconductor substrate on a side where the conductive silicon layer is formed, and removing the first SiO₂ layer in a first region containing a boundary line between the N-channel type transistor forming region and the P-channel type transistor forming region;

a first metal layer forming step of forming a first metal layer on an entire surface of the semiconductor substrate on a side where the first SiO₂ layer is formed;

a first low temperature thermal process step of performing a thermal process at a first temperature so that the first metal layer reacts with the conductive silicon layer to form a metal mono-silicide in the first region containing the boundary line;

a first metal layer removal step of removing the first metal layer in a second region other than the first region containing the boundary line;

a first high temperature thermal process step of performing a thermal process at a second temperature higher than the first temperature in the first low temperature thermal process step so that the metal mono-silicide is converted to a metal di-silicide in the first region containing the boundary line to form a metal silicide layer in a boundary inclusion portion;

a second SiO₂ layer forming step of forming a second SiO₂ layer on an entire surface of the semiconductor substrate on a side where the conductive silicon layer is formed in the boundary inclusion portion, and removing the first SiO₂ layer and the second SiO₂ layer in the second region other than the first region containing the boundary line;

a second metal layer forming step of forming a second metal layer on an entire surface of the semiconductor substrate on a side where the second SiO₂ layer is formed so that the second metal layer has a thickness different from that of the first metal layer;

a second low temperature thermal process step of performing a thermal process at a third temperature so that the second metal layer reacts with the conductive silicon layer to form a metal mono-silicide in the second region other than the first region containing the boundary line;

a second metal layer removal step of removing the second metal layer in the first region containing the boundary line;

a second high temperature thermal process step of performing a thermal process at a fourth temperature higher than the third temperature in the second low temperature thermal process step so that the metal mono-silicide is converted to a metal di-silicide in the second region other than the first region containing the boundary line to form the metal silicide layer in a boundary exclusion portion; and

a second SiO₂ layer removal step of removing the second SiO₂ layer in the first region containing the boundary line.

In the fourth aspect of the present invention, the method of producing the semiconductor device includes the second metal layer forming step of forming the second metal layer so that the second metal layer has the thickness different from that of the first metal layer. Accordingly, the metal silicide layer formed in the boundary inclusion portion in the first low temperature thermal process step and the first high temperature thermal process step has a thickness different from that of the metal silicide layer formed in the boundary exclusion portion in the second low temperature thermal process step and the second high temperature thermal process step. As a result, it is possible to produce the semiconductor similar to that in the first aspect.

In the conductive silicon layer forming step, the conductive silicon layer may be formed to have a thickness in the boundary inclusion portion the same as that in the boundary exclusion portion (within a variance range). As described above, the metal silicide layer is formed in the boundary inclusion portion in the first low temperature thermal process step and the first high temperature thermal process step through the reaction between the first metal layer and the conductive silicon layer. Further, the metal silicide layer is formed in the boundary exclusion portion in the second low temperature thermal process step and the second high temperature thermal process step through the reaction between the second metal layer and the conductive silicon layer.

Accordingly, it is possible to produce the semiconductor device in the third aspect, in which the sum of the first thickness of the metal silicide layer and the third thickness of the conductive silicon layer in the boundary inclusion portion is substantially equal to the sum of the second thickness of the metal silicide layer and the fourth thickness of the conductive silicon layer in the boundary exclusion portion (within the range of the variance).

According to a fifth aspect of the present invention, in the method of producing the semiconductor device in the fourth aspect, the first metal layer has a thickness greater than that of the second metal layer.

In the fifth aspect, the first metal layer formed in the first metal layer forming step has the thickness greater than that of the second metal layer. Accordingly, the metal silicide layer formed in the boundary inclusion portion in the first low temperature thermal process step and the first high temperature thermal process step has the thickness greater than that of the metal silicide layer formed in the boundary exclusion portion in the second low temperature thermal process step and the second high temperature thermal process step. Accordingly, it is possible to produce the semiconductor device in the second aspect.

In the present invention, it is possible to provide the semiconductor device capable of adjusting a resistivity of the metal silicide layer regardless of the thickness of the metal silicide layer in the boundary inclusion portion. Further, it is possible to provide the method of producing the semiconductor device.

### BRIEF DESCRIPTION OF THE DRAWINGS

FIGS. 1(A) and 1(B) are schematic views showing a semiconductor device according to a first embodiment of the present invention, wherein FIG. 1(A) is a schematic plan view of the semiconductor device, and FIG. 1(B) is a schematic sectional view thereof;

FIGS. 2(A) and 2(B) are schematic sectional views showing the semiconductor device according to the first embodiment of the present invention, wherein FIG. 2(A) is a schematic sectional view of the semiconductor device taken along a line 2(A)-2(A) in FIG. 1(A), FIG. 2(B) is a schematic sectional view thereof taken along a line 2(B)-2(B) in FIG. 1(A), and FIG. 2(C) is a schematic sectional view thereof taken along a line 2(C)-2(C) in FIG. 1(A);

FIG. 3 is a schematic sectional views No. 1 showing a method of producing the semiconductor device in a conductive silicon layer forming step according to the first embodiment of the present invention;

FIG. 4 is a schematic sectional views No. 2 showing a method of producing the semiconductor device in a first SiO₂ layer forming step according to the first embodiment of the present invention;

FIG. 5 is a schematic sectional views No. 3 showing a method of producing the semiconductor device in a first metal layer forming step according to the first embodiment of the present invention;

FIG. 6 is a schematic sectional views No. 4 showing a method of producing the semiconductor device in a first metal layer removal step according to the first embodiment of the present invention;

FIG. 7 is a schematic sectional views No. 5 showing a method of producing the semiconductor device in a second SiO₂ layer forming step according to the first embodiment of the present invention;

FIG. 8 is a schematic sectional views No. 6 showing a method of producing the semiconductor device in a second metal layer forming step and a second low temperature thermal process step according to the first embodiment of the present invention;

FIG. 9 is a schematic sectional views No. 7 showing a method of producing the semiconductor device in a second metal layer removal step, a second high temperature thermal process step, and a second SiO₂ layer removal step according to the first embodiment of the present invention;

FIGS. 10(A) and 10(B) are schematic views showing a semiconductor device according to a second embodiment of the present invention, wherein FIG. 10(A) is a schematic plan view of the semiconductor device, and FIG. 10(B) is a schematic sectional view thereof;

FIG. 11 is a schematic plan view showing a gate electrode of the semiconductor device according to the second embodiment of the present invention;

FIG. 12(A) is a schematic plan view showing a first conventional semiconductor device;

FIG. 12(B) is a schematic plan view showing a second conventional semiconductor device;

FIG. 13 is a graph showing a relationship between a cumulative probability of the resistivity of a gate electrode and a gate width of the gate electrode of the first conventional semiconductor device.

### DETAILED DESCRIPTION OF PREFERRED EMBODIMENTS

Hereunder, preferred embodiments of the present invention will be explained with reference to the accompanying drawings.

### First Embodiment

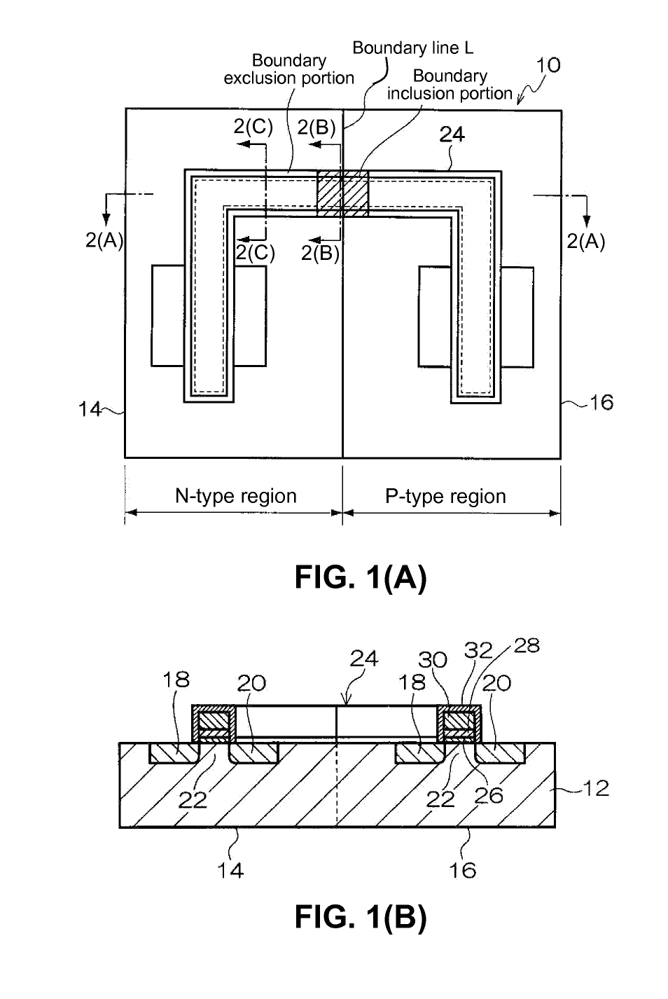

A first embodiment of the present invention will be explained. FIGS. 1(A) and 1(B) are schematic views showing a semiconductor device 10 according to the first embodiment of the present invention. More specifically, FIG. 1(A) is a schematic plan view of the semiconductor device 10, and FIG. 1(B) is a schematic sectional view thereof.

As shown in FIGS. 1(A) and 1(B), the semiconductor device 10 includes a semiconductor substrate 12. The semiconductor substrate 12 has an N-channel type transistor forming region (referred to as an N-type region) on one side thereof and a P-channel type transistor forming region 16 (referred to as a P-type region) on the other side thereof. The N-channel type transistor forming region 14 may include a P-type base member region such as a P-well (or a P-type semiconductor substrate) as a first conductive type impurity region. The P-channel type transistor forming region 16 may include an N-type base member region such as an N-well (or an N-type semiconductor substrate) as a second conductive type impurity region.

As shown in FIG. 1(B), a source diffusion layer 18 as a first diffusion layer and a drain diffusion layer 20 as a second diffusion layer are disposed in the N-type region 14 and the P-type region 16. A channel region 22 is disposed between the source diffusion layer 18 and the drain diffusion layer 20. An N-type impurity is implanted into the N-type region 14 to form the source diffusion layer 18 and the drain diffusion layer 20, and a P-type impurity is implanted into the P-type region 16 to form the source diffusion layer 18 and the drain diffusion layer 20.

In FIG. 1(B), for the sake of simple illustration, the source diffusion layer 18 and the drain diffusion layer 20 are designated with the same reference numerals in the N-type region 14 and the P-type region 16, although the source diffusion layer 18 and the drain diffusion layer 20 have different conductive types in the N-type region 14 and the P-type region 16.

In the embodiment, a gate electrode 24 is disposed on the channel region 22 of the semiconductor substrate 12 for controlling a current flowing through the channel region 22.

In the embodiment, the gate electrode 24 is disposed on a gate oxide film 26 formed as an insulation film on the semiconductor substrate 12. The gate electrode 24 is formed of a poly-silicon 28 laminated as a conductive silicon layer on the gate oxide film 26 and a metal silicide layer 30 laminated on the poly-silicon 28. An insulation film 32 formed of SiN, SiON, SiO₂, and the like is disposed to surround the gate oxide film 26, the poly-silicon 28, and the metal silicide layer 30.

In the embodiment, the gate electrode 24 is arranged to continuously extend from the channel region 22 in the N-type region 14 to the channel region 22 in the P-type region 16 such that the gate electrode 24 is disposed over a boundary line L between the N-type region 14 and the P-type region 16.

Accordingly, the source diffusion layer 18 and the drain diffusion layer 20 formed in the N-type region 14, and the gate electrode 24 formed over the channel region 22 between the source diffusion layer 18 and the drain diffusion layer 20 constitute an N-channel type MOS transistor. Further, the source diffusion layer 18 and the drain diffusion layer 20 formed in the P-type region 16, and the gate electrode 24 formed over the channel region 22 between the source diffusion layer 18 and the drain diffusion layer 20 constitute a P-channel type MOS transistor. The N-channel type MOS transistor and the P-channel type MOS transistor share the gate electrode 24.

In the embodiment, the conductive silicon layer (the poly-silicon 28) of the gate electrode 24 in the N-type region 14 is an N-type conductive layer with an N-type impurity implanted therein. The conductive silicon layer (the poly-silicon 28) of the gate electrode 24 in the P-type region 16 is a P-type conductive layer with a P-type impurity implanted therein. Accordingly, the boundary line L between the N-type region 14 and the P-type region 16 and the conductive silicon layer (the poly-silicon 28) of the gate electrode 24 near the boundary line L has a neutral state, in which the N-type impurity and the P-type impurity are mutually diffused, thereby exhibiting a high resistivity. With the configuration described above, a CMOS transistor of a dual gate type is constituted.

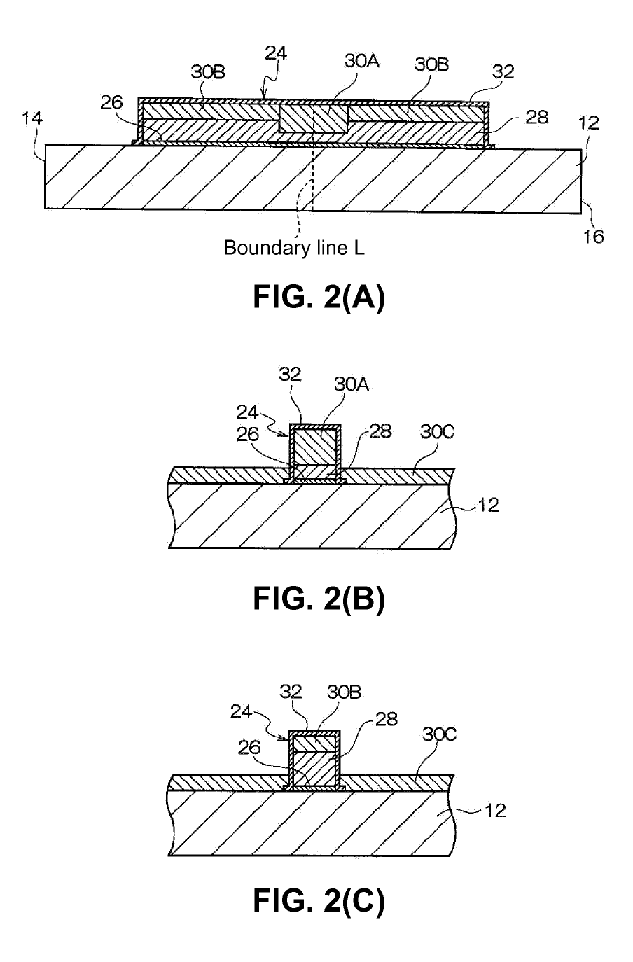

A configuration of the gate electrode 24 will be explained next in more detail with reference to FIGS. 2(A) to 2(C).

FIGS. 2(A) and 2(B) are schematic sectional views showing the semiconductor device 10 according to the first embodiment of the present invention. More specifically, FIG. 2(A) is a schematic sectional view of the semiconductor device 10 taken along a line 2(A)-2(A) in FIG. 1(A), FIG. 2(B) is a schematic sectional view thereof taken along a line 2(B)-2(B) in FIG. 1(A), and FIG. 2(C) is a schematic sectional view thereof taken along a line 2(C)-2(C) in FIG. 1(A).

In the embodiment, the gate electrode 24 includes a boundary inclusion portion disposed in a region containing the boundary line L (an NP connection portion) between the N-type region 14 and the P-type region 16 and a boundary exclusion portion disposed in a region not containing the boundary line L (the NP connection portion).

As shown in FIGS. 2(A) and 2(B), the gate electrode 24 includes a metal silicide layer 30A disposed in the boundary inclusion portion and a metal silicide layer 30B disposed in the boundary exclusion portion. The metal silicide layer 30A has a thickness greater than that of the metal silicide layer 30B. In other words, the metal silicide layer 30 has a thickness near the boundary line L (the NP connection portion) greater than a thickness in a portion other than the boundary line L (the NP connection portion).

With the configuration described above, it is possible to prevent the metal silicide layer 30 (especially, the metal silicide layer 30A disposed in the boundary inclusion portion) from being peeled off or aggregated. As a result, it is possible to prevent resistivity abnormality, in which a current does not flow smoothly in the gate electrode 24 on the boundary line L between the N-type region 14 and the P-type region 16 without increasing physically a gate width of the gate electrode 24. Further, it is not necessary to excessively increase the gate width of the gate electrode 24 in order to suppress the resistivity abnormality. Accordingly, it is possible to reduce areas of the N-type region 14 and the P-type region 16, thereby reducing a size of the semiconductor device 10.

Further, in the embodiment, the metal silicide layer 30 has the relatively small thickness in the boundary exclusion portion (the portion other than the boundary line L (the NP connection portion)), thereby preventing a resistivity of the gate electrode 24 from excessively decreasing. Accordingly, when the gate electrode 24 in an area away from the boundary line L is used as a resistor element, it is possible to obtain a sufficient level of resistivity.

It is supposed that the metal silicide layer 30 has a first thickness of the metal silicide layer 30A in the boundary inclusion portion and a second thickness of the metal silicide layer 30B in the boundary exclusion portion, and the poly-silicon 28 as the conductive silicon layer has a third thickness in the boundary inclusion portion and a fourth thickness in the boundary exclusion portion. In the embodiment, as shown in FIG. 2(A), it is configured that a sum of the first thickness and the third thickness is substantially equal to a sum of the second thickness and the fourth thickness.

In other words, in the boundary inclusion region, the metal silicide layer 30A has the relatively large thickness, and the poly-silicon 28 has the relatively small thickness. Accordingly, it is possible to adjust a total thickness of the metal silicide layer 30 and the poly-silicon 28, thereby preventing the total thickness from excessively increasing and reducing the size of the semiconductor device 10.

Note that the thickness of the metal silicide layer 30 or the poly-silicon 28 represents a length thereof in a direction perpendicular to the semiconductor substrate 12. Further, the width such as the gate width represents a length in a direction in parallel to the semiconductor substrate 12, further in a lateral direction.

A method of producing the semiconductor device 10 will be explained next. The method includes the following steps: a conductive silicon layer forming step; a first SiO₂ layer forming step; a first metal layer forming step; a first low temperature thermal process step; a first metal layer removal step; a first high temperature thermal process step; a second SiO₂ layer forming step; a second metal layer forming step; a second low temperature thermal process step; a second metal layer removal step; a second high temperature thermal process step; and a second SiO₂ layer removal step.

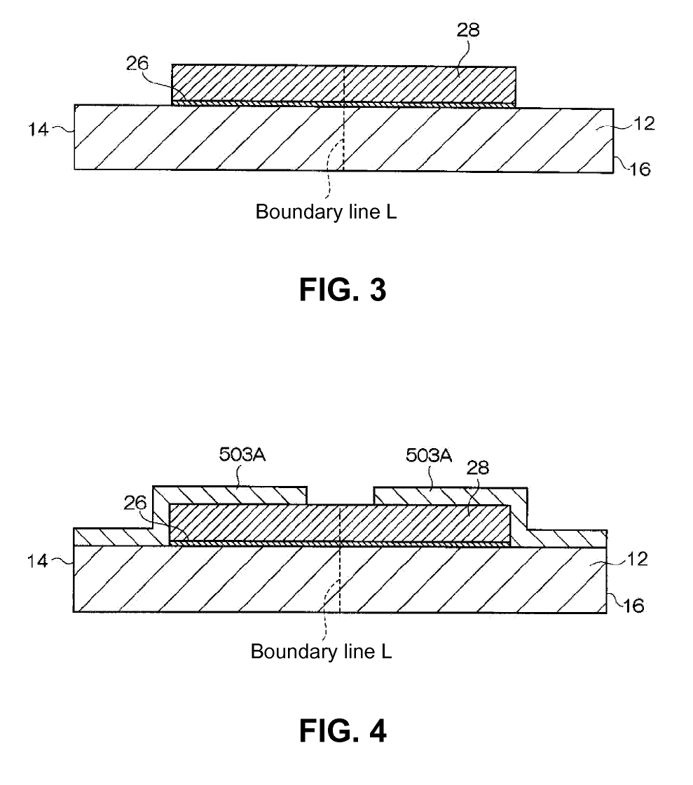

The method of producing the semiconductor device 10 will be explained with reference to FIGS. 3 to 9. FIGS. 3 to 9 are schematic sectional views No. 1 to No. 7 showing the method of producing the semiconductor device 10 according to the first embodiment of the present invention. In the following description, a Co silicide layer is formed as the metal silicide layer 30 (the metal silicide layers 30A and 30B).

In the conductive silicon layer forming step, as shown in FIG. 3, the poly-silicon 28 is formed on a surface of the semiconductor substrate 12 having the N-type region 14 and the P-type region 16, so that the poly-silicon 28 is disposed over the N-type region 14 and the P-type region 16. In this case, the poly-silicon 28 is formed on the surface of the semiconductor substrate 12 with the gate oxide film 26 in between. Note that the P-type region 16 is formed on the surface of the semiconductor substrate 12, and the poly-silicon 28 is formed on the surface of the gate oxide film 26 with a well-known method.

In the first SiO₂ layer forming step, a first SiO₂ layer (a layer containing SiO₂) 503A is formed on an entire area of the surface of the semiconductor substrate 12 on a side thereof where the poly-silicon 28 is formed. In the next step, as shown in FIG. 4, the first SiO₂ layer 503A is removed in the region containing the boundary line L (the boundary inclusion portion). Note that the first SiO₂ layer 503A is formed with a well-known method, and the first SiO₂ layer 503A is removed with a well-known method such as a photolithography method, an etching method (dry etching and wet etching) and the like.

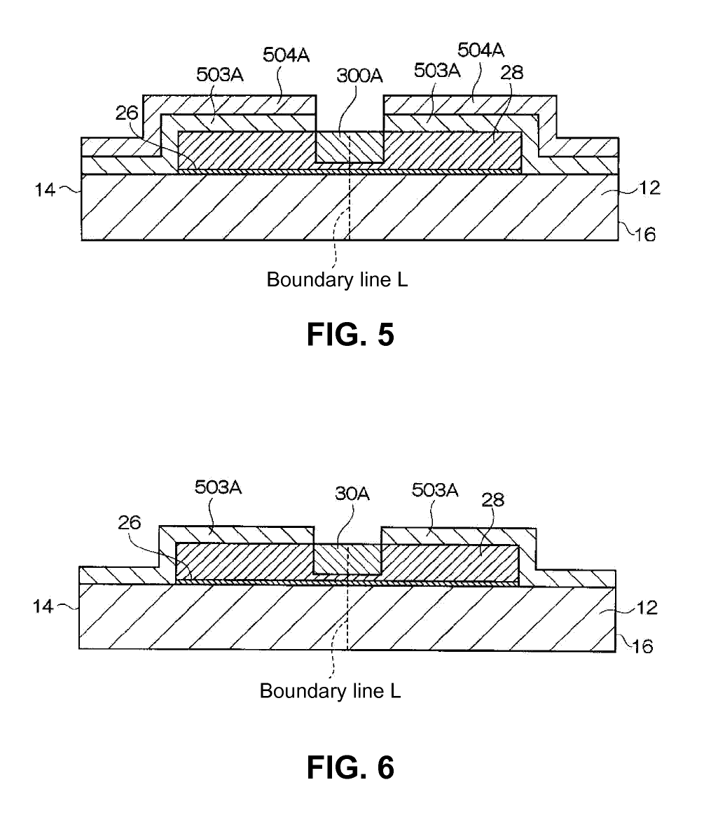

In the first metal layer forming step, as shown in FIG. 5, a Co layer 504A as a first metal layer is formed on an entire area of the surface of the semiconductor substrate 12 on a side thereof where the first SiO₂ layer 503A is formed. As described above, in the embodiment, the Co silicide layer is formed as the metal silicide layer 30. Accordingly, the Co layer 504A is formed as the first metal layer. When, for example, a Ti layer is formed as the first metal layer, it is possible to form a titanium silicide layer as the metal silicide layer 30. Similarly, when a Ni layer is formed as the first metal layer, a nickel silicide layer is formed as the metal silicide layer 30.

In the first low temperature thermal process step, a thermal process is performed, so that the Co layer 504A reacts with the poly-silicon 28 in the region containing the boundary line L (the boundary inclusion portion). Accordingly, as shown in FIG. 5, a Co mono-silicide (CoSi) layer 300A is formed. Note that the Co mono-silicide layer 300A is formed only in the region containing the boundary line L (the boundary inclusion portion), where the Co layer 504A directly contacts with the poly-silicon 28, that is, the first SiO₂ layer 503A is removed.

Note that, in the first metal layer forming step, the Co layer 504A is controlled to have a specific thickness, so that it is possible to prevent the metal silicide layer 30A disposed in the region containing the boundary line L (the boundary inclusion portion) from being peeled off or aggregated. As a result, it is possible to prevent resistivity abnormality in the gate electrode 24 near the boundary line L.

In the first low temperature thermal process step, the thermal process is performed with a well-known method such as a method using an RTA (Rapid Thermal Annealing) device. It is preferred that the thermal process is performed at a temperature less than 550° C., such that Co mono-silicide (CoSi) is effectively created and Co di-silicide (CoSi₂) is not created to a large extent.

In the first metal layer removal step, the Co layer 504A as the first metal layer is removed from a region other than the region containing the boundary line L (the boundary inclusion portion). The Co layer 504A is removed with a well-known method such as a solution process using a mixture of ammonium and hydrogen peroxide.

In the first high temperature thermal process step, after the Co layer 504A is removed from the region other than the region containing the boundary line L (the boundary inclusion portion), a thermal process is performed at a temperature higher than the temperature in the first low temperature thermal process step. As a result, as shown in FIG. 6, the Co mono-silicide (CoSi) layer 300A further reacts with the poly-silicon 28, thereby forming the metal silicide layer 30A in the boundary inclusion portion.

The thermal process is performed with a method similar to that in the first low temperature thermal process step. It is preferred that the thermal process is performed at a temperature greater than 700° C., such that Co mono-silicide (CoSi) is effectively converted to Co di-silicide (CoSi₂).

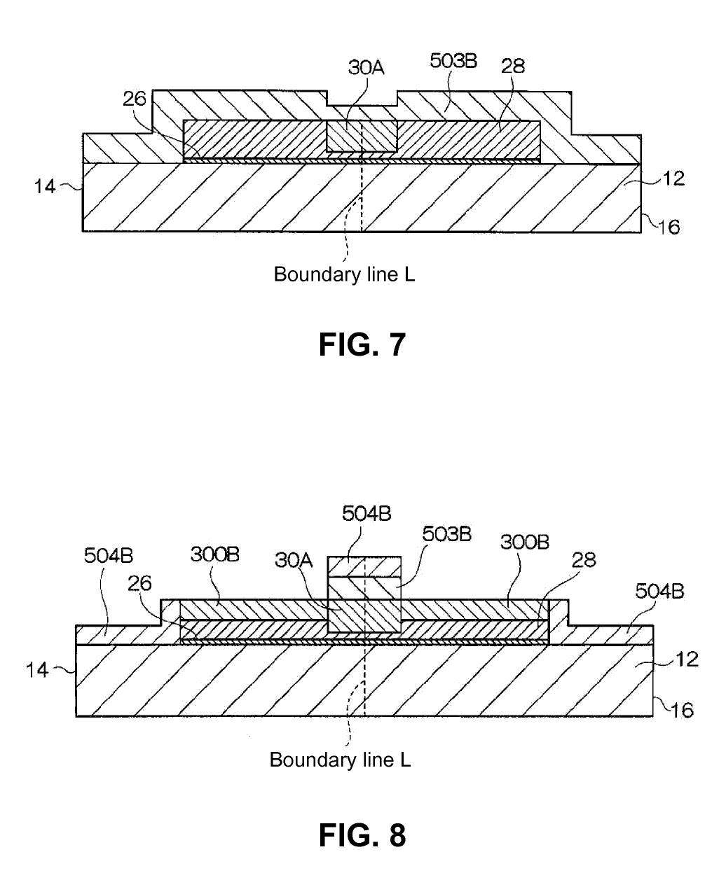

In the second SiO₂ layer forming step, after the metal silicide layer 30A is formed in the region containing the boundary line L (the boundary inclusion portion), a second SiO₂ layer (a layer containing SiO₂) 503B is formed on an entire area of the surface of the semiconductor substrate 12 on a side thereof where the metal silicide layer 30A is formed. Accordingly, as shown in FIG. 7, the second SiO₂ layer 503B is integrated with the first SiO₂ layer 503A (refer to FIG. 6) to form a single layer.

In the next step, as shown in FIG. 8, the second SiO₂ layer 503B is removed in the region other than the region containing the boundary line L (the boundary inclusion portion). In this step, the first SiO₂ layer 503A previously formed is removed as well. Note that the second SiO₂ layer 503B is formed with a well-known method, and the second SiO₂ layer 503B is removed with a well-known method similar to that in the first SiO₂ layer forming step.

In the step, it is preferred that the second SiO₂ layer 503B is formed in the region of the boundary inclusion portion where the metal silicide layer 30A is already formed. Alternatively, the second SiO₂ layer 503B may be formed in a region of the boundary inclusion portion slightly smaller than the region where the metal silicide layer 30A is already formed. More specifically, the second SiO₂ layer 503B may be formed in a region of the boundary inclusion portion slightly inside the region where the metal silicide layer 30A is already formed in a longitudinal direction of the gate electrode 24 (a lateral direction in FIG. 8).

When the second SiO₂ layer 503B is formed in the region described above, a Co layer 504 formed as a second metal layer in the second metal layer forming step (described later) overlaps with the metal silicide layer 30A already formed. Accordingly, it is possible to continuously form the metal silicide layer 30A in the boundary inclusion portion with respect to the metal silicide layer 30B in the boundary exclusion portion.

In the second metal layer forming step, after the second SiO₂ layer 503B is removed in the region other than the region containing the boundary line L (the boundary inclusion portion), a Co layer 504B as a second metal layer is formed on an entire area of the surface of the semiconductor substrate 12 on a side thereof where the first SiO₂ layer 503B remains only in the region containing the boundary line L (the boundary inclusion portion).

In the embodiment, the metal silicide layer 30B in the region other than the region containing the boundary line L (the boundary exclusion portion) has the thickness smaller than that of the metal silicide layer 30A in the region containing the boundary line L (the boundary inclusion portion). Accordingly, the Co layer 504B is adjusted to have the thickness smaller than the Co layer 504A formed in the first metal layer forming step. Further, the Co layer 504A is adjusted to have a specific thickness, thereby forming the metal silicide layer 30B having a specific thickness for a desired sheet resistivity.

In the second low temperature thermal process step, a thermal process is performed, so that the Co layer 504B reacts with the poly-silicon 28 in the region other than the region containing the boundary line L (the boundary inclusion portion). Accordingly, as shown in FIG. 8, a Co mono-silicide (CoSi) layer 300B is formed. Note that the Co mono-silicide layer 300B is formed only in the region other than the region containing the boundary line L (the boundary inclusion portion), where the Co layer 504B directly contacts with the poly-silicon 28, that is, the poly-silicon 28 is formed and the second SiO₂ layer 503B does not remain.

In the second low temperature thermal process step, the thermal process is performed with a method similar to that in the first low temperature thermal process step. It is preferred that the thermal process is performed at a temperature less than 550° C., such that Co mono-silicide (CoSi) is effectively created and Co di-silicide (CoSi₂) is not created to a large extent.

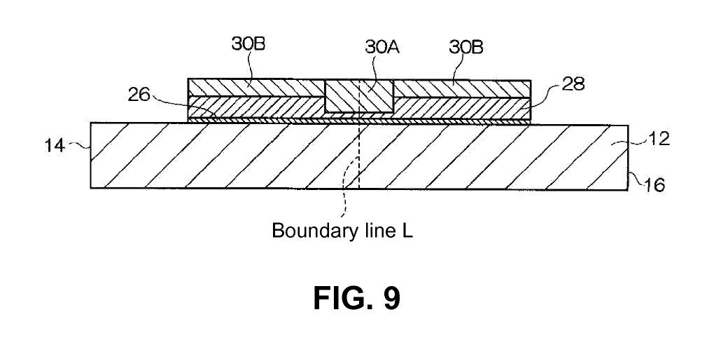

In the second metal layer removal step, as shown in FIG. 9, the Co layer 504B as the second metal layer is removed from the region containing the boundary line L (the boundary inclusion portion), and the Co layer 504B as the second metal layer is removed from the region where the poly-silicon 28 is not formed. The Co layer 504B is removed with a method similar to that in the first low temperature thermal process step.

In the second high temperature thermal process step, after the Co layer 504B is removed from the region containing the boundary line L (the boundary inclusion portion), a thermal process is performed at a temperature higher than the temperature in the second low temperature thermal process step. As a result, as shown in FIG. 9, the Co mono-silicide (CoSi) layer 300B further reacts with the poly-silicon 28 in the region other than the region containing the boundary line L (the boundary inclusion portion) to create a metal di-silicide (CoSi₂), thereby forming the metal silicide layer 30B in the boundary exclusion portion.

The thermal process is performed with a method similar to that in the second low temperature thermal process step. It is preferred that the thermal process is performed at a temperature greater than 700° C., such that Co mono-silicide (CoSi) is effectively converted to Co di-silicide (CoSi₂).

In the second SiO₂ layer removal step, as shown in FIG. 9, the second SiO₂ layer 503B is removed from the region containing the boundary line L (the boundary inclusion portion). The second SiO₂ layer 503B is removed with a well-known method.

In the next step, the insulation film 32 formed of SiN, SiON, SiO₂, and the like is formed with a well-known method, thereby producing the semiconductor device 10 shown in FIG. 2(A).

As described above, in the embodiment, the method of producing the semiconductor device 10 includes the first metal layer forming step, in which the Co layer 504A as the first metal layer is formed to have the thickness greater than that of the Co layer 504B as the second metal layer. Accordingly, the metal silicide layer 30A in the boundary inclusion portion formed in the first low temperature thermal process step and the first high temperature thermal process step has the thickness greater than that of the metal silicide layer 30B in the boundary exclusion portion formed in the second low temperature thermal process step and the second high temperature thermal process step.

Further, in the embodiment, the poly-silicon 28 as the conductive silicon layer formed in the conductive silicon layer forming step has the thickness at a same level (within a range of variance) in the boundary inclusion portion and the boundary exclusion portion. Further, in the first low temperature thermal process step and the first high temperature thermal process step, the Co layer 504A as the first metal layer reacts with the poly-silicon 28 as the conductive silicon layer, thereby forming the metal silicide layer 30A in the boundary inclusion portion.

Further, in the second low temperature thermal process step and the second high temperature thermal process step, the Co layer 504B as the second metal layer reacts with the poly-silicon 28 as the conductive silicon layer, thereby forming the metal silicide layer 30B in the boundary exclusion portion. Accordingly, the metal silicide layer 30 and the poly-silicon 28 have the total thickness at a same level (within a range of variance) in the boundary inclusion portion and the boundary exclusion portion.

### Second Embodiment

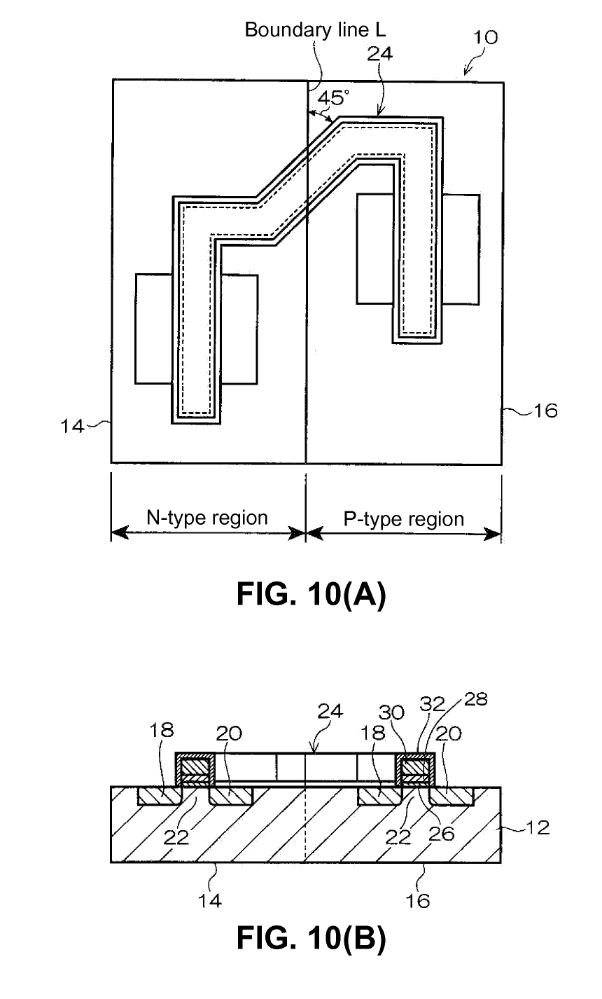

A second embodiment of the present invention will be explained next. FIGS. 10(A) and 10(B) are schematic views showing the semiconductor device 10 according to the second embodiment of the present invention. More specifically, FIG. 10(A) is a schematic plan view of the semiconductor device 10, and FIG. 10(B) is a schematic sectional view thereof.

In the first embodiment, as shown in FIG. 2(A), the metal silicide layer 30A in the boundary inclusion portion has the thickness greater than that of the metal silicide layer 30B in the boundary exclusion portion. In the second embodiment, as shown in FIG. 10(A), a similar configuration is applied to the gate electrode 24 disposed to obliquely cross the boundary line L in a state inclined in a clockwise direction by 45 decrees.

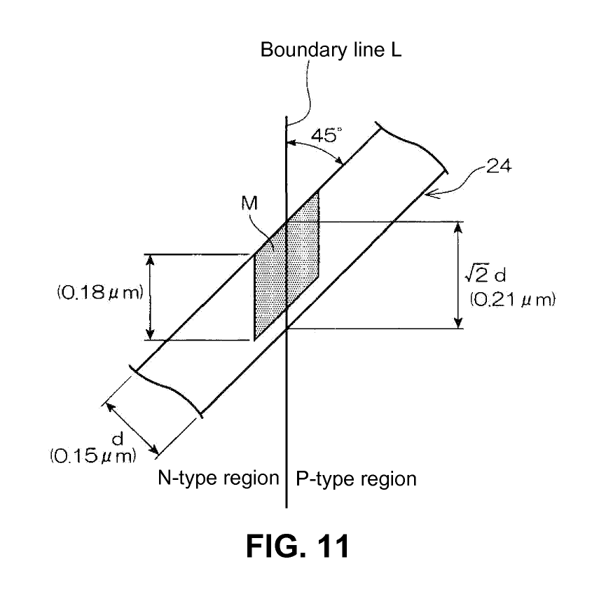

FIG. 11 is a schematic plan view showing the gate electrode 24 of the semiconductor device 10 according to the second embodiment of the present invention. As shown in FIG. 11, when the gate electrode 24 is arranged in the state inclined with respect to the boundary line L, the gate electrode 24 crosses the boundary line L between the N-type region 14 and the P-type region 16 in a crossing region (an NP butting portion). When the gate electrode 24 has a width d (a gate width), the crossing region (the NP butting portion) has a region width (an effective gate width relative to the NP butting portion) of \sqrt{2d}.

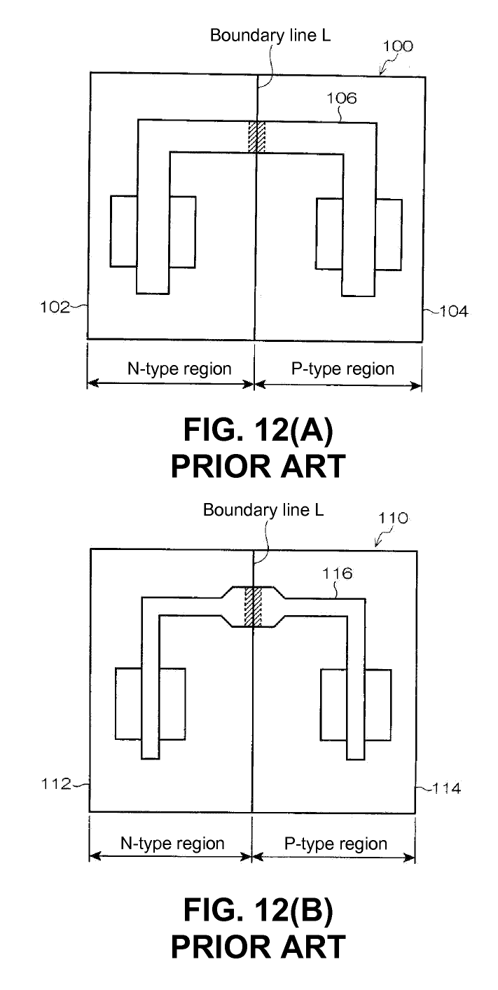

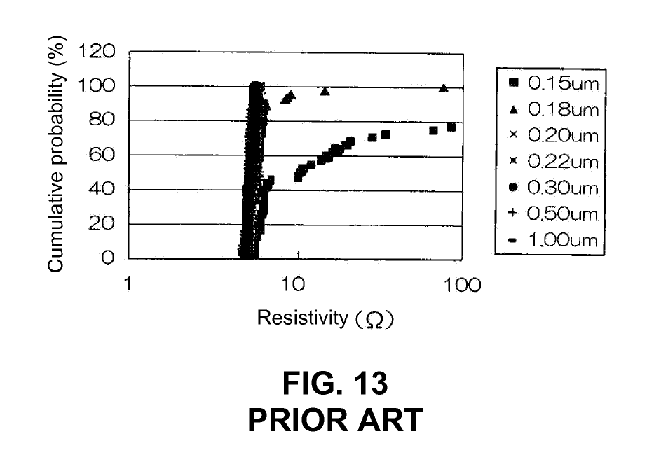

As described in the section of BACKGROUND OF THE INVENTION AND RELATED ART STATEMENT, as shown in FIG. 12(A), the conventional semiconductor device 100 has the gate electrode 106 crossing perpendicularly relative to the boundary line L between the N-type transistor forming region 102 and the P-type transistor forming region 104.

As compared with the conventional semiconductor device, in the semiconductor device 10 in the embodiment, it is possible to increase the effective gate width of the gate electrode 24 relative to the NP butting portion by about 1.4 times. In other words, it is possible to increase the effective gate width without increasing the gate width of the gate electrode 24. Accordingly, it is possible to prevent the resistivity abnormality, in which a gate current does not flow smoothly in the gate electrode 24 on the boundary line L between the N-type region 14 and the P-type region 16. Further, it is not necessary to excessively increase the gate width of the gate electrode 24 in order to suppress the resistivity abnormality. Accordingly, it is possible to reduce areas of the N-type region 14 and the P-type region 16, thereby reducing the size of the semiconductor device 10.

As described above, in the embodiment, the gate electrode 24 is disposed to obliquely cross the boundary line L between the N-type region 14 and the P-type region 16 in the state inclined in the clockwise direction by 45 decrees. In this case, it is suffice that the gate electrode 24 is disposed to obliquely cross the boundary line L, and the crossing angle is not limited to 45 degrees relative to the boundary line L.

When the gate electrode 24 is disposed to obliquely cross the boundary line L at the crossing angle greater than 45 degrees, it is necessary to increase the gate width of the gate electrode 24 for obtaining an effective gate width large enough to prevent the resistivity abnormality. When the gate electrode 24 is disposed to obliquely cross the boundary line L at the crossing angle less than 45 degrees, the gate electrode 24 has a larger length along the boundary line L. Accordingly, it is necessary to increase the sizes of the N-type region 14 and the P-type region 16 depending on a layout.

In view of the cases described above, it is preferred that the gate electrode 24 is disposed to obliquely cross the boundary line L between the N-type region 14 and the P-type region 16 in the state inclined in the clockwise direction by 45 decrees in order to effectively suppress the resistivity abnormality.

In an actual case, the gate electrode 24 may be disposed to obliquely cross the boundary line L at a slightly shifted angle due to a mask shift. In view of the shift, when the gate electrode 24 is disposed to obliquely cross the boundary line L at the crossing angle not excessively deviated from 45 degrees, more specifically, when the gate electrode 24 is disposed to obliquely cross the boundary line L at the crossing angle 45±5 degrees (between 40 and 50 degrees), it is possible to ignore the shift. When it is possible to increase the gate width in a specific layout, it is possible to arrange the gate electrode 24 to obliquely cross the boundary line L at the crossing angle greater than 45 degrees. Further, it is possible to arrange the gate electrode 24 to obliquely cross the boundary line L at the crossing angle smaller than 45 degrees in a specific layout without increasing the sizes of the N-type region 14 and the P-type region 16.

The disclosure of Japanese Patent Application No. 2009-032762, filed on Feb. 16, 2009, is incorporated in the application by reference.

While the invention has been explained with reference to the specific embodiments of the invention, the explanation is illustrative and the invention is limited only by the appended claims.

What is claimed is:

1. A semiconductor device, comprising:
a semiconductor substrate;
an N-channel type transistor forming region formed on the semiconductor substrate;
a P-channel type transistor forming region formed on the semiconductor substrate and arranged adjacent to the N-channel type transistor forming region; and
a gate electrode formed on the semiconductor substrate over the N-channel type transistor forming region and the P-channel type transistor forming region, said gate electrode having a boundary inclusion portion formed in a first region including a boundary line between the N-channel type transistor forming region and the P-channel type transistor forming region and a boundary exclusion portion formed in a second region not including the boundary line, said gate electrode including a conductive silicon layer and a metal silicide layer formed on a surface of the conductive silicon layer, said metal silicide layer having a first thickness in the boundary inclusion portion and a second thickness different from the first thickness in the boundary exclusion portion.

2. The semiconductor device according to claim 1, wherein said metal silicide layer has the first thickness greater than the second thickness.

3. The semiconductor device according to claim 1, wherein said conductive silicon layer has a third thickness in the boundary inclusion portion and a fourth thickness in the boundary exclusion portion so that a sum of the first thickness and the third thickness is more than 70% and less than 130% of a sum of the second thickness and the fourth thickness.

4. The semiconductor device according to claim 1, wherein said gate electrode is formed to cross the boundary line in an inclined state.

5. The semiconductor device according to claim 1, wherein said gate electrode is formed to cross the boundary line in a state inclined relative to the boundary line substantially by 45 degrees.

6. A method of producing a semiconductor device, comprising:
a conductive silicon layer forming step of forming a conductive silicon layer over an N-channel type transistor forming region and a P-channel type transistor forming region both formed on a semiconductor substrate;
a first SiO₂ layer forming step of forming a first SiO₂ layer on an entire surface of the semiconductor substrate on a side where the conductive silicon layer is formed, and removing the first SiO₂ layer in a first region containing a boundary line between the N-channel type transistor forming region and the P-channel type transistor forming region;
a first metal layer forming step of forming a first metal layer on an entire surface of the semiconductor substrate on a side where the first SiO₂ layer is formed;
a first low temperature thermal process step of performing a thermal process at a first temperature so that the first metal layer reacts with the conductive silicon layer to form a metal mono-silicide in the first region containing the boundary line;
a first metal layer removal step of removing the first metal layer in a second region other than the first region containing the boundary line;
a first high temperature thermal process step of performing a thermal process at a second temperature higher than the first temperature in the first low temperature thermal process step so that the metal mono-silicide is converted to a metal di-silicide in the first region containing the boundary line to form a metal silicide layer in a boundary inclusion portion;
a second SiO₂ layer forming step of forming a second SiO₂ layer on an entire surface of the semiconductor substrate on a side where the conductive silicon layer is formed in the boundary inclusion portion, and removing the first SiO₂ layer and the second SiO₂ layer in the second region other than the first region containing the boundary line;
a second metal layer forming step of forming a second metal layer on an entire surface of the semiconductor substrate on a side where the second SiO₂ layer is formed so that the second metal layer has a thickness different from that of the first metal layer;
a second low temperature thermal process step of performing a thermal process at a third temperature so that the second metal layer reacts with the conductive silicon layer to form a metal mono-silicide in the second region other than the first region containing the boundary line;
a second metal layer removal step of removing the second metal layer in the first region containing the boundary line;
a second high temperature thermal process step of performing a thermal process at a fourth temperature higher than the third temperature in the second low temperature thermal process step so that the metal mono-silicide is converted to a metal di-silicide in the second region other than the first region containing the boundary line to form the metal silicide layer in a boundary exclusion portion; and
a second SiO₂ layer removal step of removing the second SiO₂ layer in the first region containing the boundary line.

7. The method of producing the semiconductor device according to claim 6, wherein, in the first metal layer forming step, the first metal layer is formed to have a thickness greater than that of the second metal layer.
